(19) United States
(12) Patent Application Publication
(10) Pub. No.: US 2007/0134861 A1
(43) Pub. Date: Jun. 14, 2007

(54) Semiconductor devices and methods of manufacture thereof

(76) Inventors: Jin-Ping Han, Fishkill, NY (US); Renee Tong Mo, Briarcliff Manor, NY (US); Tsong Lin Leo Tai, Stormville, NY (US); Anita Madan, Danbury, CT (US); Nivo Rovedo, LaGrangeville, NY (US); Victor Ku, Yorktown Heights, NY (US); Martin M. Frank, Bronx, NY (US); Daeyoung Lim, Suwon-Si (KR); Richard Haight, Mahopac, NY (US)

Correspondence Address: SLATER & MATSIL LLP, 17950 PRESTON ROAD, SUITE 1000, DALLAS, TX, 75252, US

(21) Appl. No.: 11/300,147

(22) Filed: Dec. 14, 2005

(51) Int. Cl. H01L 21/8234

(52) U.S. Cl. 438/197

(57) ABSTRACT

Semiconductor devices and methods of manufacture thereof are disclosed. A preferred embodiment includes providing a workpiece, forming a gate dielectric material over the workpiece, the gate dielectric material comprising an insulator and at least one metal element, and forming a conductive material over the gate dielectric material. The conductive material comprises the at least one metal element of the gate dielectric material.

### TECHNICAL FIELD

The present invention relates generally to the fabrication of semiconductor devices, and more particularly to the fabrication of transistors.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET). A transistor typically includes a gate dielectric disposed over a channel region, and a gate formed over the gate dielectric.

The most common materials typically used are silicon dioxide (SiO₂) as a gate dielectric material and polysilicon as a gate material. These materials have been preferred materials for transistors for many years because of their superior physical and electrical properties on a silicon substrate. However, the rapid progress in the scaling or reduction in size of transistors, including a reduction in the thickness of the gate dielectric, is pushing the limit of the use of these materials, because of unacceptable leakage current.

MOSFETs having a gate dielectric comprising SiO₂ and a gate material comprising polysilicon suffer from a poly-depletion effect and/or a gate-depletion effect, because the gate electric field inverts a channel within the substrate and depletes the polysilicon gate; i.e., holes or electrons are pushed away in the polysilicon gate proximate the gate dielectric. Thus, the gate capacitance is decreased; i.e., the effective electrical thickness of the gate dielectric is increased, resulting in drive current degradation. Drive current degradation is a critical performance issue, and can result in a large interconnect capacitance signal delay in an interconnect network (e.g., comprising conductive lines), for example.

The poly-depletion effect is particularly problematic for dual-poly (e.g., the gates of the PMOS (pMOSFET) device and NMOS (nMOSFET) device are implanted with different dopant species) complementary MOS (CMOS) devices in scaled CMOS technology, as shown in FIG. 1 and FIG. 2. FIG. 1 shows graphs of Cᵢₙᵥ/C_{acc} as a function of the gate dielectric thickness tₒₓ for an NMOS transistor and a PMOS transistor, wherein C_{acc} represents capacitance between the gate and the substrate under conditions of majority carrier accumulation (i.e., when majority carrier concentration is enhanced) near the substrate surface, and Cᵢₙᵥ represents capacitance between the gate and the substrate under conditions of inversion (i.e., when minority carrier concentration is higher than majority carrier concentration) near the substrate surface. FIG. 1 illustrates that as the gate dielectric thickness tₒₓ is decreased, the poly depletion effect becomes more severe. FIG. 2 illustrates normalized capacitance C/C_{acc} as a function of applied gate voltage for nMOSFETs (e.g., N poly having a dopant species concentration of about 7×10¹⁹ cm⁻³) with two gate dielectric thicknesses, one for a gate dielectric thickness tₒₓ of 2 nm and another for a gate dielectric thickness tₒₓ of3 nm. The asymmetry of the curves indicates a severe polysilicon depletion effect at these thicknesses of gate dielectric material, and thus indicates an inability to further scale down the thickness of the gate dielectric materials.

There is a trend in the semiconductor industry toward the use of high dielectric constant (k) dielectric materials having a dielectric constant or k value of greater than 4.0, for example, as a potential replacement for SiO₂ as gate dielectric materials. For example, hafnium-based dielectric materials are one type of high k dielectric material under consideration for use as a gate dielectric. Although a significant reduction in leakage current has been achieved by the use of high k dielectric materials as gate dielectric materials, some serious problems still remain, such as the poly depletion effect and the formation of poor quality ultra-thin uniform high-k dielectric films (e.g., the films are non-continuous when deposited), which further hamper the scaling or reduction in size of CMOS technology.

Thus, what are needed in the art are improved transistor designs and methods of manufacture thereof.

### SUMMARY OF THE INVENTION

These and other problems are generally solved or circumvented, and technical advantages are generally achieved, by preferred embodiments of the present invention, which provide novel methods of forming transistors and structures thereof.

In accordance with a preferred embodiment of the present invention, a method of manufacturing a semiconductor device includes providing a workpiece, forming a gate dielectric material over the workpiece, the gate dielectric material comprising an insulator and at least one metal element, and forming a conductive material over the gate dielectric material. The conductive material comprises the at least one metal element of the gate dielectric material.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows graphs of Cᵢₙᵥ/C_{acc} as a function of the gate dielectric thickness tₒₓ for a prior art NMOS (nMOSFET) transistor and PMOS (pMOSFET) transistor;

FIG. 2 is a graph of C/C_{acc} for two prior art gate dielectric thicknesses, indicating a severe poly depletion effect in a prior art NMOS transistor;

FIGS. 3 through 8 show cross-sectional views of a semiconductor device at various stages of manufacturing in accordance with a preferred embodiment of the present invention;

FIGS. 9 and 10 show cross-sectional views of a semiconductor device at various stages of manufacturing in accordance with another preferred embodiment of the present invention;

FIG. 11 shows a cross-sectional view of a CMOS device manufactured in accordance with an embodiment of the present invention;

FIGS. 12 is a graph of capacitance versus voltage of a transistor manufactured in accordance with an embodiment of the present invention that does not exhibit a poly depletion effect;

FIG. 13 shows graphs of normalized X-ray photoelectron spectroscopy (XPS) counts versus binding energy for several types of dielectric materials;

FIG. 14 shows graphs of normalized XPS counts versus binding energy for several types of dielectric materials; and

FIG. 15 shows graphs of ultraviolet photoelectron spectroscopy (UPS) counts versus binding energy for a HfSiON gate dielectric formed using various processing conditions, showing a conductive material layer formed at certain anneal process temperatures.

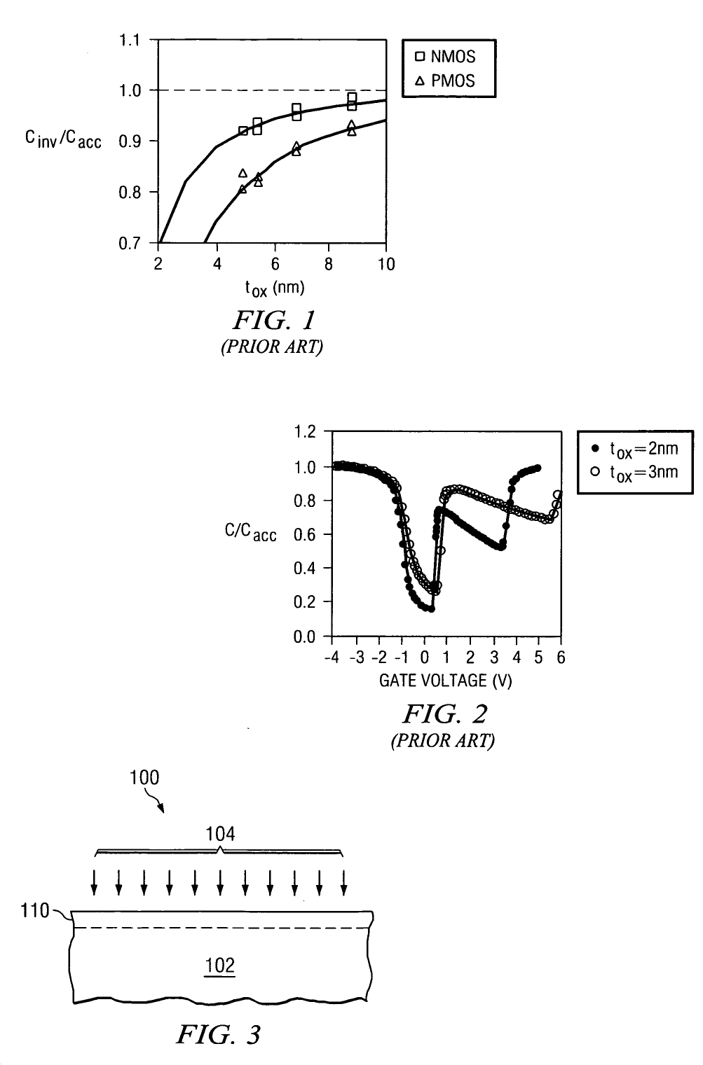

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Various approaches have been tried to alleviate the poly depletion problem, but the prior art approaches have serious drawbacks. For example, in a paper entitled, “A Polycrystalline-Si₁₋ₓGeₓ-Gate CMOS Technology,” by T. King et al., published in IEDM, 1990, pp. 253-256, which is incorporated herein by reference, the use of polySiGe for a gate electrode is disclosed, which may be able to increase the dopant solubility and therefore the dopant concentration in the polysilicon. However, the process described is quite complicated. Furthermore, the Ge concentration control has an effect on the work function of the gate electrodes: because of this, control of the threshold voltage Vₜ can be problematic. Additionally, oxides of Ge are soluble in water, making gate profile control difficult.

Another approach to solve the poly depletion problem involves the use of laser thermal processing, as described in a paper entitled, “Reduction of Polysilicon Gate Depletion Effect in NMOS Devices Using Laser Thermal Processing” by Y. F. Chong, et al., in Electrochemical and Solid-State Letters 7, 2004, pp. G25-G27, which is incorporated herein by reference. Laser thermal processing may enhance the non-equilibrium concentration of the solid solution of the gate dielectric material. However, drawbacks of this approach include a high cost and many unknown factors, such as the laser annealing or temperature distribution variation is extremely sensitive to surface reflection. Other disadvantages include a deleterious effect of higher activation energy on fixed charge density, junction leakage, gate leakage, and reliability.

In yet another approach, described in a paper entitled, “Feasibility of using W/TiN as Metal Gate for Conventional 0.13 μm CMOS Technology and Beyond,” by J. C. Hu, et al., IEDM, 1997, pp. 825-828, which is also incorporated herein by reference, the use of metal as a material for gates is disclosed. However, disadvantages of this approach include the introduction of metal deposition into conventional CMOS process integration, for which there is a concern for metal thermal stability with the gate dielectric and/or polysilicon gate. Etching, adhesion, and contamination problems are obstacles to be overcome, as well. In addition, the increased complexity of the CMOS manufacturing process due to the metal gate deposition process results in a higher cost. The complexity of the interface between the metal and gate dielectric may contribute to the unstable work function problem that this approach tends to create.

The present invention will be described with respect to preferred embodiments in a specific context, namely in the fabrication of CMOS devices. The invention may also be applied, however, to the fabrication of other transistor devices where the formation of a dielectric material adjacent a conductive material is required, for example.

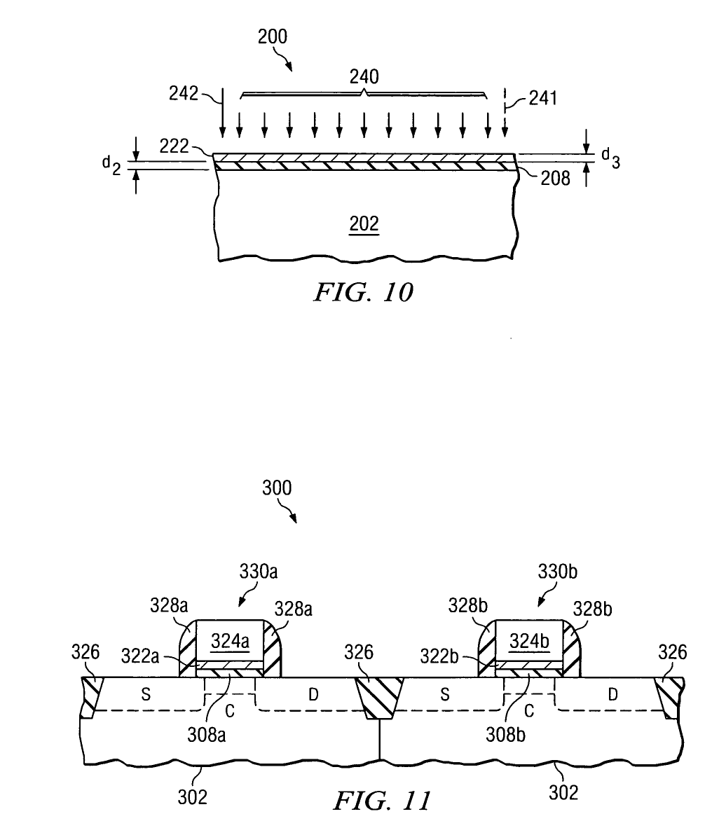

Embodiments of the present invention achieve technical advantages by providing novel methods of forming transistors and structures thereof. In some embodiments, the gate dielectric material is exposed to a treatment process to form a conductive material at a top portion of the gate dielectric material, shown in FIGS. 3 through 8. In other embodiments, a conductive material is formed in-situ at a top portion of the gate dielectric material, by altering the substances introduced into a chamber during the deposition of the gate dielectric material, as shown in FIGS. 9 and 10.

FIGS. 3 through 8 show cross-sectional views of a semiconductor device 100 at various stages of manufacturing in accordance with a preferred embodiment of the present invention. Referring next to FIG. 3, first, a workpiece 102 is provided. The workpiece 102 may include a semiconductor substrate comprising silicon or other semiconductor materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) substrate, for example.

The surface of the workpiece 102 may be cleaning using a pre-gate cleaning process, e.g., to remove any contaminants or native oxide from the top surface of the workpiece 102. The pre-gate cleaning process may comprise NH₄OH, H₂O₂, and H₂O; HCl, H₂O₂, and H₂O; or HF and H₂O; as examples, although the pre-gate cleaning process may alternatively comprise other chemistries.

In an optional step, the workpiece 102 is exposed to a pretreatment process 104 to form an interface region 1 10 near the top surface of the workpiece 102, as shown in FIG. 3. The pretreatment process 104 may comprise exposing the workpiece 102 to O₂, O₃, N₂, H₂, NO, N₂O, SiH₄, other oxygen-containing gases, other nitrogen-containing gases, or combinations thereof, as examples, although alternatively, other chemistries may be used. The optional pretreatment process 104 prepares the surface of the workpiece 102 for the bonding of the gate dielectric material to be deposited, for example. The pretreatment process 104 causes an interface region 110 to form at the top surface of the workpiece 102, as shown. The interface region 110 may comprise a thickness of about 5 to 20 Angstroms, for example, although alternatively, the interface region 110 may comprise other dimensions. The interface region 110 may comprise a thickness of about 30 Angstroms or less, for example. The interface region 110 may comprise a region of silicon bonded with oxygen, as an example, although alternatively, the interface region 110 may comprise other materials.

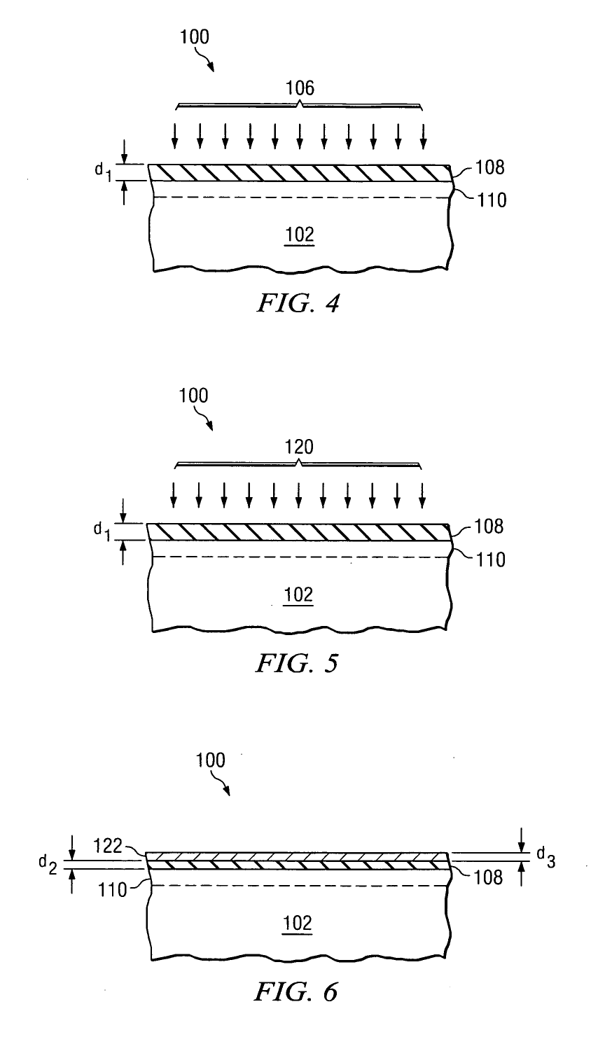

In another embodiment, the interface region 110 is formed during the deposition process 106 to form the gate dielectric material 108, as shown in FIG. 4, to be described further herein.

Next, a deposition process 106 is used to form a gate dielectric material 108 over the top surface of the workpiece 102, as shown in FIG. 4. The deposition process 106 preferably comprises chemical vapor deposition (CVD), atomic layer deposition (ALD), or physical vapor deposition (PVD), as examples, although alternatively, other deposition processes may be used. The deposition process 106 preferably comprises forming a gate dielectric material 108 comprising Hf, Zr, La, Al, Ti, Ta, Sr, Bi, Ba, Y, Pr, Pb, Sm, Eu, Nd, Sc, Mg, Co, W, Ir, Si, Be, Ce, Gd, Dy, Ga, and/or Pd combined with O, N, C, and/or Si, as examples, although the gate dielectric material 104 may also comprise other materials. For example, the gate dielectric material 108 may comprise Al₂O₃, AlₓSi_{y}O_{z}, BaTiO₃, SrTiO₃, (Ba,Sr)TiO₃, BeAl₂O₄, CeO₂, CeHfO₄, CoTiO₃/Si₃N₄, Dy₂O₃, DyScO₃, EuAlO₃, Ga₂O₃, Gd gallium oxide, GdScO₃, HfO₂, Hf silicate, HfₓTa_{y}O_{z}, HfTiO₄, La₂O₃, LaAlO₃, LaScO₃, La₂SiO₅, MgAl₂O₄, NdAlO₃, PrAlO₃, SmAlO₃, SrTiO₃, Ta₂O₅, Ta₂O₅—TiO₂, TiO₂, TiO₂/Si₃N₄, Y₂O₃, YₓSi_{y}O_{z}, ZrO₂, Zr—Al—O, Zr silicate, ZrTiO₄, SnTiO₄, Pb(Zr,Ti)O₃, materials containing these elements at different stoichiometric compositions, or combinations or multiple layers thereof, as examples, although the gate dielectric material 108 may comprise other insulating materials. The gate dielectric material 108 preferably comprises a high k dielectric material having a dielectric constant of about 4.0 or greater, for example.

The gate dielectric material 108 preferably comprises a thickness of about 20 to 40 Angstroms or less, depending on the dielectric constant of the gate dielectric material 108, for example, although alternatively, the gate dielectric material 108 may comprise other dimensions, for example. The thickness of the gate dielectric material 108 may comprise a thickness comprising dimension d₁, as shown.

The gate dielectric material 108 preferably includes a metal element in one embodiment. For example, the metal element preferably comprises Hf, Zr, La, Al, Ti, Ta, Sr, Bi, Ba, Y, Pr, Pb, Sm, Eu, Nd, Sc, Mg, Co, W, Ir, Be, Ce, Gd, Dy, Ga, and/or Pd, or combinations thereof, although alternatively, the metal element may comprise other materials. The gate dielectric material 108 preferably comprises at least one metal element, for example.

In one embodiment, the deposition process 106 for the gate dielectric material 108 results in the formation of an interface region 110. In this embodiment, the optional pretreatment process 104 previously described herein to form an interface region 110 is not required. Rather, the interface region 110 forms as a result of the deposition process 106. For example, if the deposition process 106 comprises depositing Hf, the interface region 110 may comprise Si—O, Hf—O and/or Hf—Si—O bonds. The interface region 110 preferably comprises a thickness of about 20 Angstroms or less, and reduces the effective oxide thickness (EOT) (e.g., of the gate dielectric material 108) of the transistor, for example.

After the gate dielectric material 108 is formed, the surface of the gate dielectric material 108 may subjected to an optional first treatment process (not shown in the figures). The first treatment process may comprise exposing the surface of the gate dielectric material 108 to SiH₄, SiCl₂H₂, di-silane, diluted SiF₄, or other silicon-containing substances, as examples, although alternatively, other materials may also be used. The optional first treatment process prevents an increase in the thickness of the interface region 110, smoothes the surface of the gate dielectric material 108, and/or cures defects in the gate dielectric material 108 and/or the interface region 110, as examples. In one embodiment, for example, the optional first treatment process may prevent pinning of the threshold voltage, which can occur in MOSFET devices with high k materials as a gate dielectric material, as an example.

Next, in accordance with embodiments of the present invention, the top surface of the gate dielectric material 108 is treated with a second treatment process 120, as shown in FIG. 5. The second treatment process 120 is a preferably novel treatment process that converts a portion, e.g., a top portion, of the gate dielectric material 108 to a conductive material 122, as shown in FIG. 6.

The novel second treatment process 120 may comprise a thermal nitridation process, a plasma nitridation process, a gate dielectric material reduction process, or a catalytic reaction process, as examples, although other methods of converting a portion of the gate dielectric material 108 to a conductive material 122 may also be used. Preferred second treatment processes 120 will be described next.

In one embodiment, the second treatment process 120 comprises a thermal nitridation process, for example. The workpiece 102 is preferably heated in a chamber in the presence of a nitrogen-containing gas, e.g., at a temperature of about 700 to 800 degrees C. The gate dielectric material 108 may be exposed to a nitrogen-containing gas such as NH₃ for about 20 to 60 minutes, as examples. However, other temperatures, gases, and processing times may also be used. For example, if the gate dielectric material 108 comprises a metal element M, Si and O, then the thermal nitridation process results in the reaction: MSiO+NH₃→MN or MSiN. Thus, the conductive material 122 comprises MN or MSiN in this embodiment, comprising a thickness of about 10 Angstroms or less, although alternatively, the conductive material 122 may comprise other conductive materials and dimensions, for example.

In another embodiment, the second treatment process 120 comprises a plasma nitridation process, for example. The workpiece 102 is preferably exposed to plasma in a chamber in the presence of a nitrogen-containing gas, e.g., at a temperature of about 200 to 300 degrees C. The gate dielectric material 108 may be exposed to a nitrogen-containing gas such as NH₃ for about 20 to 300 seconds, as an example, although other temperatures, gases and processing times may be used. For example, if the gate dielectric material 108 comprises a metal element M, Si, and O, then the plasma nitridation process results in the reaction: MSiO+NH₃→MN or MSiN. Thus, the conductive material 122 comprises MN or MSiN in this embodiment comprising a thickness of about 10 Angstroms or less, although alternatively, the conductive material 122 may comprise other conductive materials and dimensions, for example.

If the second treatment process 120 comprises a thermal or plasma nitridation process, the second treatment process 120 preferably comprises exposing the gate dielectric material 108 to a nitrogen-containing gas, optionally combined with an O₂, CO, or CO₂, as examples.

In another embodiment, the second treatment process 120 comprises a gate dielectric material 108 reduction process, for example. The gate dielectric material reduction process preferably comprises exposing the gate dielectric material 108 to a hydrogen species, e.g., at a lower temperature and then to a higher temperature, during exposure to a reduction reaction activation energy. The temperatures may vary depending on the level of the reduction reaction activation energy, for example. The temperatures may comprise about 450 to 750 degrees C., as examples, although other temperatures may be used. The exposure to the hydrogen species preferably comprises exposing the gate dielectric material 108 to a hydrogen-containing gas such as H₂, as an example. Alternatively, other temperatures, hydrogen-containing gases, or deuterium-containing gases may also be used. For example, if the gate dielectric material 108 comprises a metal element M, and if the gate dielectric material 108 also comprises Si and O, then the gate dielectric material reduction process results in the reaction: MSiO+H→MSi+OH or H₂O. Thus, the conductive material 122 comprises MSi in this embodiment comprising a thickness of about 10 Angstroms or less, although alternatively, the conductive material 122 may comprise other conductive materials and dimensions, for example. The hydrogen species removes oxygen away from the gate dielectric material 108 in this embodiment, for example, and forms a conductive material 122 at a top surface of, e.g., at a top portion of the gate dielectric material 108. The byproducts of the gate dielectric reduction process, OH and/or H₂O, may be removed using a cleaning process or may be vaporized, for example.

In yet another embodiment, the second treatment process 120 comprises a catalytic reaction process, for example. The gate dielectric material 108 is preferably exposed to a catalyst, such as a metal organic precursor such as MO(CH₂)ₓ. Alternatively the catalyst may comprise a dielectric material, such as MO or MSiO, as examples. The gate dielectric material 108 is preferably exposed to the catalyst or the metal organic precursor at a temperature sufficient to cause a catalytic reaction, e.g., at a temperature greater than room temperature, for about 30 minutes or less, as examples. Alternatively, other catalysts, temperatures, and processing times may be used. For example, if the gate dielectric material 108 comprises a metal element M, Si, and O, then the catalytic reaction process results in the reaction: MSiO+Catalyst or Metal-organic precursor→MSi. Thus, the conductive material 122 comprises MSi in this embodiment, comprising a thickness of about 10 Angstroms or less, although alternatively, the conductive material 122 may comprise other conductive materials and dimensions, for example.

After the second treatment process 120, the conductive material 122 is disposed on the top surface of the gate dielectric material 108, as shown in FIG. 6. The gate dielectric material 108 has a thickness d₂, and the conductive material 122 has a thickness d₃, wherein the gate dielectric material 108 thickness d₂ and the conductive material 122 thickness d₃ together may comprise substantially the original thickness d₁ (see FIG. 5) of the gate dielectric material 108 before the second treatment process 120, for example.

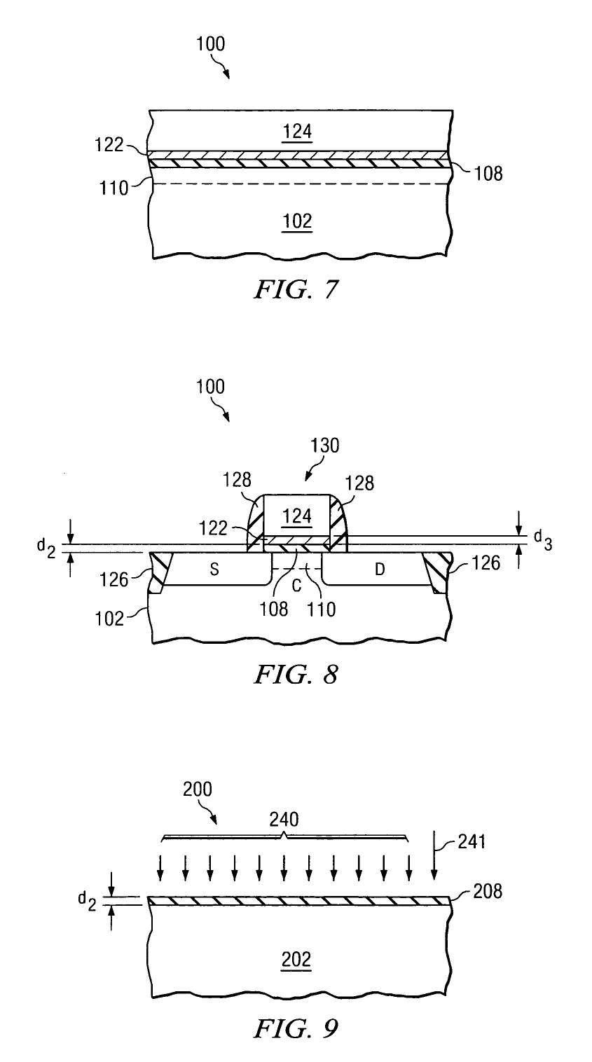

Next, a layer of semiconductor material 124 is formed on the top surface of the conductive material 122, as shown in FIG. 7. The layer of semiconductive material 124 preferably comprises polysilicon having a thickness of about 700 to 1,200 Angstroms and may be deposited using CVD, as examples. Alternatively, the layer of semiconductive material 124 may comprise other materials and dimensions, and the layer of semiconductive material 124 may be deposited using other deposition techniques.

The manufacturing process of the semiconductor device 100 is then continued, as shown in FIG. 8. For example, the layer of semiconductive material 124, the conductive material 122, and the gate dielectric material 108 may be patterned, e.g., using lithography, to form a gate dielectric 108 and gate electrode 122/124 of a transistor device 130. Sidewall spacers 128 may be formed on the sidewalls of the layer of semiconductive material 124, the conductive material 122, and the gate dielectric material 108. Isolation regions 126 may be formed between active areas of the workpiece 102, e.g., to separate adjacent transistors 130. Source S and drain D regions may be formed in the workpiece 102 proximate the gate dielectric 108 by implanting dopant species into the workpiece 102 top surface, as shown. A channel C of the transistor device may be formed between the source S and drain D regions, as shown.

One or more insulating materials (not shown) may be deposited over the transistor 130, and contacts (also not shown) may be formed in the insulating materials in order to make electrical contact with the gate 122/124, source S and/or drain D. Additional metallization and insulating layers may be formed and patterned over the top surface of the insulating material and contacts. A passivation layer may be deposited over the insulating layers. Bond pads may be formed over contacts, and the semiconductor device 100 may then be singulated or separated into individual die. The bond pads may be connected to leads of an integrated circuit package (not shown) or other die, for example, in order to provide electrical contact to the transistor 130 of the semiconductor device 100.

The novel treatment process 120 of embodiments of the present invention advantageously converts a portion of the gate dielectric material 108 to a conductive material 122 disposed over the top surface of the gate dielectric material 108, reducing the thickness of the gate dielectric material 108 and creating a conductive and/or metallic surface, e.g., on the top surface of the conductive material 122, with improved adhesion and bonding properties for the layer of semiconductor material 124 that is formed over the conductive material 122. The gate electrode of the transistor 130 comprises the conductive material 122 and the layer of semiconductive material 124.

Only one transistor is shown in FIGS. 3 through 8; however, a plurality of transistors 130, e.g., hundreds, thousands, millions, or billions, may be formed simultaneously in accordance with embodiments of the present invention. The transistor 130 may comprise an NMOS device or a PMOS device, for example. If the transistor 130 comprises a PMOS device, then preferably a P type material is used for the gate dielectric material 108 and/or gate electrode material 122 and 124, for example, in one embodiment. As an example, the novel treatment 120 may comprise a gate dielectric reduction process that is used to form P type materials 108, 122, and 124. Likewise, if the transistor 130 comprises an NMOS device, then preferably an N type material is used for the gate dielectric material 108 and/or gate electrode material 122 and 124, for example. As examples, the novel treatment process 120 may comprise a thermal or plasma nitridation process that is used to form N type materials 108, 122 and 124.

In another preferred embodiment of the present invention, the conductive material 222 is formed in-situ as part of the deposition process 240 for the gate dielectric material 208, as shown in a cross-sectional view in FIGS. 9 and 10. Like numerals are used for the various elements that were described in FIGS. 3 through 8. To avoid repetition, each reference number shown in FIGS. 9 and 10 is not described again in detail herein. Rather, similar materials and processes x02, x08, etc. . . . are preferably used for the various material layers shown as were described for FIGS. 3 through 8, where x=1 in FIGS. 3 through 8 and x=2 in FIGS. 9 and 10. As an example, the preferred and alternative materials and dimensions described for the gate dielectric material 108 in the description for FIGS. 3 through 8 are preferably also used for the gate dielectric material 208 of FIGS. 9 and 10.

In this embodiment, during the deposition process of the gate dielectric material 208 shown in FIG. 9, a first substance 242 (see FIG. 10) is introduced after a predetermined amount of time to form the conductive material layer 222, as shown in FIG. 10. For example, the deposition process to form the gate dielectric material 208 preferably comprises at least one second substance 240 comprising at least one metal element and a third substance 241. The at least one second substance 240 preferably comprises the at least one metal element comprising Hf, Zr, La, Al, Ti, Ta, Sr, Bi, Ba, Y, Pr, Pb, Sm, Eu, Nd, Sc, Mg, Co, W, Ir, Be, Ce, Gd, Dy, Ga, and/or Pd, or combinations thereof, as examples, although other metal elements may be used. The at least one second substance 240 may comprise a gas or fluid, for example, and in some embodiments, preferably comprises a precursor of the at least one metal element. The at least one second substance 240 may comprise an organic ligand combined with the at least one metal element, for example. The at least one second substance 240 may comprise a vaporized gas in some embodiments, for example. Two or more second substances 240 may be introduced; for example, a second substance 240 comprising a Hf precursor and a second substance 240 comprising a Ti precursor may be simultaneously introduced into the chamber to form HfTiO, although two or more other second substances 240 comprising other metal precursors may also be used.

The third substance 241 preferably comprises a reaction gas that is adapted to convert the precursor metal element of the at least one second substance 240 into a material layer, e.g., to form the gate dielectric material 208 on the workpiece 202. The third substance 241 may comprise O₂ or O₃, as examples, although alternatively, the third substance 241 may comprise other gases. The third substance 241 may be adapted to oxidize the metal element of the at least one second substance 240 and form a metal oxide of the metal element, for example, forming an insulating material that comprises the gate dielectric material 208, as shown in FIG. 9. The workpiece 202 is preferably exposed to the at least one second substance 240 and the third substance 241 for a predetermined period of time until an insulating material is formed on the workpiece 202 comprising a predetermined thickness d₂ of the gate dielectric material 208.

Next, without removing the workpiece 202 from the chamber, the substances 240 and 241 introduced into the chamber are preferably altered to cause the formation of a conductive material 222, as shown in FIG. 10. For example, in one embodiment, the third substance 241 is discontinued from being introduced into the chamber, and the first substance 242 is introduced into the chamber. The first substance 242 preferably comprises a different substance than the third substance 241 in this embodiment. A valve may be opened part-way into the deposition process to introduce the first substance 242, for example. The at least one second substance 240 is continued to be introduced into the chamber with the first substance 242, as shown in FIG. 10, until the desired thickness d₃ of the conductive material layer 222 is formed. The manufacturing process steps described with reference to FIGS. 7 and 8 are then continued to complete the semiconductor device 200, for example.

In another embodiment, to form the conductive material layer 222, rather than introducing a first substance 242, a reduced amount of the third substance 241 is introduced into the chamber with the at least one second substance 240, as shown in phantom in FIG. 10. For example, a conductive material layer 222 may be formed that comprises an oxide of the metal element of the at least one second substance 240 that is conductive rather than insulative, such as indium oxide. In this embodiment, the amount of third substance 241 introduced into the chamber is reduced after the formation of the dielectric material layer 208, to form a layer of conductive material 222 that is conductive, rather than introducing a first substance 242 that is different than the third substance 241.

As an example, after the workpiece 202 is placed into a deposition chamber, a first portion of the deposition process comprises introducing the at least one second substance 240 and the third substance 241 into the deposition chamber. The first portion of the deposition process may be continued for a predetermined time period, e.g., about 10 minutes. The first portion of the deposition process may include introducing at least one second substance 240 containing at least one metal element M and a third substance 241 such as O₂ to form a dielectric material layer 208 comprising MO₂ that includes the metal element M (e.g., comprising a metal element as described for the embodiment shown in FIGS. 3 through 8) and having a thickness of about 20 Angstroms. A second portion of the deposition process comprises introducing the first substance 242 into the chamber while the third substance 241 is ramped down or the valve supplying the third substance 241 is turned off. The first substance 242 may comprise a nitrogen-containing gas such as NH₃, for example, resulting in the formation of a conductive material layer 222 comprising MN over the dielectric material layer 208, for example, having a thickness of about 20 Angstroms. Alternatively, the first substance 242, the at least one second substance 240, and the third substance 241 may comprise other gases, for example.

The in-situ flow deposition embodiment shown in FIGS. 9 and 10 is advantageous in that the method is easily implemented into existing manufacturing process flows, for example. A separate deposition process for forming the conductive material layer 222 is not required in this embodiment, for example.

Advantageously, a CMOS device may be manufactured comprising a PMOS transistor 330a and an NMOS transistor 330b, as shown in FIG. 11 in a cross-sectional view. The PMOS transistor 330a is also referred to as a PMOS device, and the NMOS transistor 330b is also referred to as an NMOS device, herein. Again, like numerals are used for the various elements that were described in the previous figures, and to avoid repetition, each reference number shown in FIG. 11 is not described again in detail herein.

Part of the workpiece 302 may be masked while another part is processed as described herein. P type materials 308a, 322a, and 324a may be formed on the PMOS device 330a, and N type materials 308b, 322b, and 324b may be formed on the NMOS device 330b in this manner, for example.

In one embodiment, a different treatment process (such as the treatment process 120 shown in FIG. 5) or in-situ deposition process (such as the in-situ deposition process shown in FIGS. 9 and 10) is preferably used to form the conductive material 322a of the PMOS device 330a than the treatment process or in-situ deposition process that is used to form the conductive material 322b of the NMOS device 330b. One portion of the workpiece 302 may be masked with a layer of photoresist and/or a hard mask comprising an oxide and/or nitride material, as examples, while another portion is exposed to a treatment process or in-situ deposition process, for example.

As an example, before the deposition of the gate dielectric material 308a and 308b, the NMOS device 330b portion of the workpiece 302 may be masked, and the conductive material 322a of the PMOS device 330a may be formed by depositing the gate dielectric material 308a, and converting a portion of the gate dielectric material 308a to the conductive material 322a using a treatment process (such as the treatment process 120 shown in FIG. 5). The masking material, gate dielectric material 308a and conductive material 322 are then removed from over the NMOS device 330b portion of the workpiece 302. The PMOS device 330a portion of the workpiece 302 is then masked. The gate dielectric material 308b is deposited, and the conductive material 322b of the NMOS device 330b may be formed by an in-situ deposition process (such as the in-situ deposition process shown in FIGS. 9 and 10). The mask, gate dielectric material 308b, and the conductive material 322b are then removed from over the PMOS device 330a portion.

In another embodiment, rather than using an in-situ deposition process to form the NMOS device 330b portion, a different treatment process may be used than was used for the PMOS device 330a portion. For example, the gate dielectric material 308a and 308b may be formed in a single deposition step over the entire workpiece 302, and then two different treatment processes may be used to form the conductive material 322a and 322b for the PMOS device 330a and NMOS device 330b, respectively, by masking one portion of the workpiece 302 while the other portion of the workpiece 302 is treated.

Advantageously, treatment processes 120, in-situ deposition processes, and materials 308a, 322a, 324a, 308b, 322b, and 324b may be selected to optimally integrate the processes described herein into a CMOS device manufacturing process flow, for example.

Also, the gate dielectric of a transistor may be substantially reduced in thickness in accordance with embodiments of the present invention. For example, referring to FIG. 4, the gate dielectric material 108 thickness as deposited preferably comprises a thickness d₁ of about 30 Angstroms or less. The treatment process 120 shown in FIG. 5 converts a portion of the gate dielectric material 108 to a conductive material 122 having a thickness d₃, with the remaining gate dielectric material 108 having a thickness d₂ of about 20 Angstroms or less, for example, as shown in FIG. 6. The resulting gate dielectric material 108 preferably has an effective electrical thickness of about 20 Angstroms or less after the treatment process 120, in accordance with embodiments of the present invention.

Experimental results of embodiments of the present invention show that functional devices may be formed based on the embodiments described herein. For example, a high k dielectric material 108 comprising HfSiO (where indices to denote stoichiometry are omitted) was converted into a conductive material 122 comprising HfSiN or HfSiON (where indices to denote stoichiometry are omitted) using a thermal nitridation process 120. The thermal nitridation process 120 was easily implemented into a conventional CMOS device process flow, and a poly depletion effect was eliminated. A uniform inversion thickness Tᵢₙᵥ was formed for devices across a 12 inch wafer, for example.

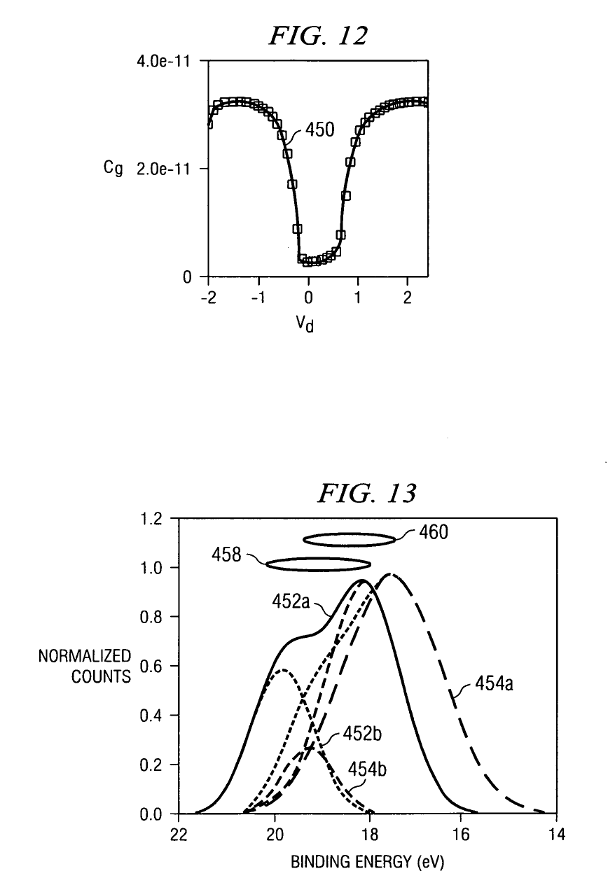

FIG. 12 shows a graph of gate capacitance C_{g} versus drain voltage V_{d}; in particular, the gate voltage tested with the substrate (drain and source) grounded, of a transistor manufactured in accordance with an embodiment of the present invention that is absent a poly depletion effect. A C-V graph 450 is shown for a transistor wherein the gate dielectric material 108 comprising HfSiO was exposed to a thermal nitridation process 120. Advantageously, the graph 450 is symmetric, indicating no poly depletion effect. Similar data results were found on devices formed across an entire wafer for multiple wafers in the same lot, indicating good uniformity and controllability of the novel processes described herein.

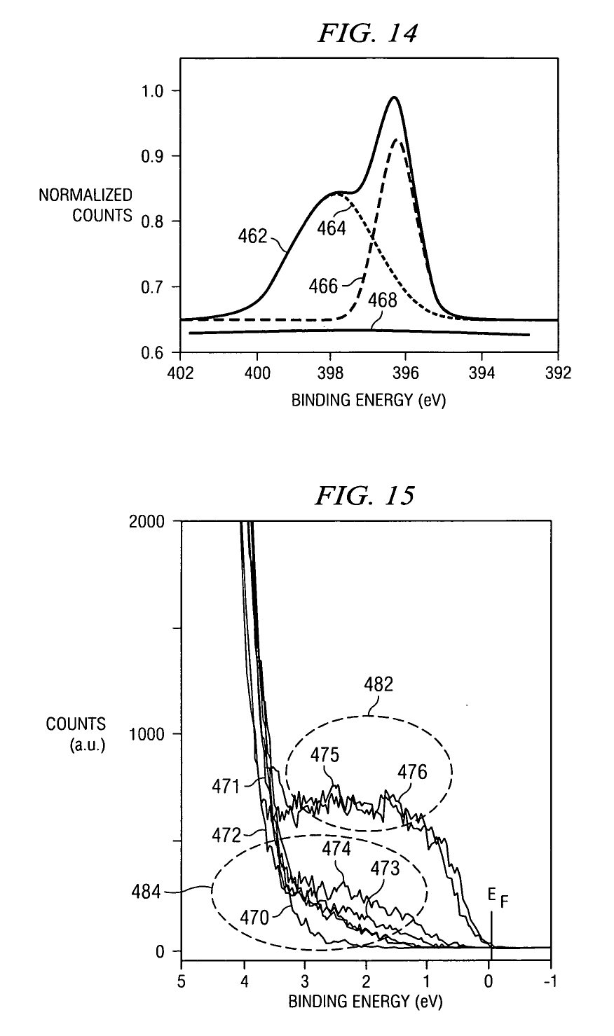

FIGS. 13 and 14 show XPS graphs of normalized counts versus binding energy for several types of dielectric materials in accordance with embodiments of the present invention. In FIG. 13, an Hf-4f profile (e.g., a photoemission signal originating from electrons of hafnium at a fourth orbital level and f spin sub-level) is shown, wherein graphs 452a and 452b show binding energy for a sample of HfSiO annealed using N₂ at 775 degrees C. Graphs 454a and 454b show binding energy for a sample of HfSiO annealed using NH₃ at 775 degrees C. Hf—O bonds are shown at range 458, e.g., at the peaks in the graphs 454b and 454a at approximately 20 eV to 18 eV, respectively. Hf—N bonds are shown at range 460, e.g., at the peaks in the graphs 452b and 452a at approximately 19 eV to 17 eV, respectively.

In FIG. 14, an N-1s profile (e.g., a photoemission signal originating from electrons of nitrogen at first orbital level and s spin sub-level) is shown, wherein graph 462 shows binding energy for a sample of HfSiO annealed using NH₃ at 775 degrees C. Graphs 464 and 466 show de-convoluted energy levels of N-1s electrons of graph 462. Graph 468 shows binding energy for a sample of HfSiO annealed using N₂ at 775 degrees C.

FIG. 13 illustrates that the Hf-4f profile of an NH₃ annealed sample reveals a significant shift to lower binding energy in comparison with the HfSiO sample with N₂ annealing, indicating that some Hf—O bonds are likely converted into Hf—N bond with an NH₃ treatment, and also indicating that the binding energy positions are in good agreement with Hf—N binding peak positions. FIG. 14 confirms the previous observation that additional N1s peaks are observed on HfSiO sample anneal under NH₃. The low binding energy observed (e.g., around 396 eV) comprises evidence of the formation of Hf—N bonding. No N1s peak was detected when HfSiO was annealed under N₂.

FIG. 15 shows graphs of UPS counts versus binding energy for a HfSiO gate dielectric 108 and a conductive material 122 comprising HfSiON formed using various anneal temperatures. UPS measurements were performed in order to determine the impact of NH₃ anneal treatment processes 120 on the electronic structure of a gate dielectric material 108 comprising HfSiO near the valence band edge. UPS data for a gate dielectric material 108 comprising HfSiO disposed on Si substrates having an orientation of (100) subjected to a variety of annealing treatments 120 are shown in FIG. 15. The high k dielectric films 108 were formed by CVD growth of HfSiO followed by a mild anneal in O₂; subsequently, and in the same furnace, a final high-temperature anneal was performed in NH₃. The deposition time was 20 minutes, and the high-temperature anneal was performed in NH₃, which leads to N incorporation into the film stack 108/122. Samples were then unloaded into ambient air and, after several weeks, introduced into an ultra-high vacuum (UHV) system. There, UPS spectra were recorded before and after performing additional anneal processes in either UHV or NH₃, all in the same vacuum system (e.g., ‘in situ’).

FIG. 15 shows a UPS spectrum for as deposited HfSiON (using a 20 minute deposition and a NH₃ anneal process) that is characteristic of an insulating material. However, subsequent UHV anneal processes successively gave rise to an increasing density of gap states. Gap state density is moderate after anneals to temperatures between 150 and 650° C. For example, graph 470 shows results with no anneal, e.g., as deposited. Graph 471 shows results after a 150 degree C. anneal; graph 472 shows results after a 300 degree C. anneal; graph 473 shows results after a 500 degree C. anneal; and graph 474 shows results after a 650 degree C. anneal. However, after anneals to 800 and 900 degrees C., shown at graphs 475 and 476, respectively, gap state density is high at binding energies as low as 0.75 eV, indicating the development of states near the Fermi-level energy EF. This demonstrates that a material with near-metallic electronic characteristics is formed under these conditions in regions 482 (graphs 475 and 476), compared to regions 484 (graphs 470, 471, 472, 473, and 474) where metallic electronic characteristics are not exhibited. The data from FIG. 15 demonstrates that, in the range of processing conditions studied, HfSiO attains gap states and near-metallic, e.g., highly conductive, properties if a high-temperature NH₃ anneal is performed. Other factors that affect the results of the anneal process include the length or time of the anneal process and the pressure, as examples.

Advantageously, the formation of the conductive material 122/222/322 results in a material stack for a gate electrode/gate dielectric of a transistor that results in the elimination of a poly depletion effect. The conductive material 122/222/322 may be very thin; e.g., it may comprise a few monolayers of conductive material. A conductive material 122/222/322 having a thickness of about 5 to 10 Angstroms or less is adequate to screen electrostatic interaction between poly-Si and gate dielectrics, therefore eliminating the poly depletion effect.

Converting part of high-k gate dielectric 108/208/308 (e.g., comprising a metal oxide) into a conductive material layer 122/222/322 results in the consumption of part of the high k material layer 108/208/308, and also makes the high k material layer 108/208/308 thinner and more uniform, which cannot be easily achieved by deposition techniques, therefore providing the ability to scale down device 100/200/300 sizes even further. The conductive material 122/222/322 forms a process-induced metal bond between the gate dielectric material 108/208/308 and the layer of semiconductive material 124/324. MOSFET devices comprising polysilicon gates 124/324 and high k gate dielectric materials 108/208/308 may be further scaled or reduced in size, and have improved device performance, in accordance with embodiments of the present invention, without a significant increase in manufacturing costs.

Advantageously, an additional metal deposition step is not required to form the conductive material 122/222/322 described herein. The treatment processes and in-situ deposition processes described herein are used to form a conductive material 122/222/322 that forms a metallic bond or thin conductive layer 122/222/322 between the polysilicon (e.g., the layer of semiconductor material 124/324) and the high-k dielectric material (the gate dielectric material 108/208/308).

Appropriate conditions can be used to form a metallic bond/thin metal layer 122/222/322 between polysilicon 124/324 and the high k dielectric material 108/208/308, such as M-N, M-Si, M-C, or M-Si—N bonds. For example, the conductive material 122 may comprise M-N, M-Si, M-C, or M-Si—N bonds between the layer of semiconductive material 124 and the gate dielectric material 108. One example is nitridation-induced metallic bonds on hafnium-based high k dielectric materials 108/208/308 such as HfO₂ or HfSiO. Sources for the conductive material 122/222/322 may comprise a reaction between poly-silicon and the high k dielectric materials 108/208/308, such as HfSiON forming HfSiN or HfSi bonds; or nitridation itself, forming HfN bonds, as examples.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, the method comprising:
providing a workpiece;
forming a gate dielectric material over the workpiece, the gate dielectric material comprising an insulator and at least one metal element; and
forming a conductive material over the gate dielectric material using a treatment process of the gate dielectric material, the conductive material comprising the at least one metal element of the gate dielectric material.

2. The method according to claim 1, wherein the treatment process of the gate dielectric material comprises a thermal nitridation process, a plasma nitridation process, a gate dielectric material reduction process, or a catalytic reaction process.

3. The method according to claim 1, further comprising forming an interface region on the surface of the workpiece, before or during forming the gate dielectric material over the workpiece.

4. The method according to claim 1, further comprising exposing the gate dielectric material to SiH₄, SiCl₂H₂, di-silane, diluted SiF₄, or other silicon-containing substances, before forming the conductive material over the gate dielectric material.

5. The method according to claim 1, further comprising forming a layer of semiconductive material over the conductive material, and patterning the layer of semiconductive material, the conductive material, and the gate dielectric material, wherein the gate dielectric material comprises a gate dielectric of at least one transistor, and wherein the conductive material and the layer of semiconductive material comprise a gate electrode of the at least one transistor.

6. The method according to claim 5, wherein patterning the layer of semiconductive material, the conductive material, and the gate dielectric material comprises forming at least one PMOS transistor and at least one NMOS transistor, wherein forming the conductive material comprises using a first treatment process of the gate dielectric material, or using a first in-situ deposition process to form a first conductive material for the at least one PMOS transistor, and wherein forming the conductive material comprises using a second treatment process of the gate dielectric material, or using a second in-situ deposition process for the at least one NMOS transistor, wherein the second treatment process or the second in-situ deposition process is different than the first treatment process or the first in-situ deposition process.

7. A method of manufacturing a semiconductor device, the method comprising;
providing a workpiece;
forming a gate dielectric material over the workpiece, the gate dielectric material comprising an insulator; and
converting a portion of the gate dielectric material to a conductive material.

8. The method according to claim 7, wherein converting the portion of the gate dielectric material to a conductive material comprises treating the gate dielectric material, and wherein treating the gate dielectric material comprises a thermal nitridation process, a plasma nitridation process, a gate dielectric material reduction process, or a catalytic reaction process.

9. The method according to claim 7, wherein converting the portion of the gate dielectric material comprises treating the gate dielectric material with a thermal nitridation process, wherein the thermal nitridation process comprises heating the workpiece to a temperature of about 700 to 800 degrees C. and exposing the gate dielectric material to a nitrogen-containing gas for about 20 to 60 minutes.

10. The method according to claim 9, wherein exposing the gate dielectric material to the nitrogen-containing gas comprises exposing the gate dielectric material to a nitrogen-containing gas combined with O₂, CO, or CO₂.

11. The method according to claim 7, wherein converting the portion of the gate dielectric material comprises treating the gate dielectric material with a plasma nitridation process, wherein the plasma nitridation process comprises exposing the gate dielectric material to plasma at a temperature of about 200 to 300 degrees C. and exposing the gate dielectric material to a nitrogen-containing gas for about 20 to 300 seconds.

12. The method according to claim 11, wherein exposing the gate dielectric material to the nitrogen-containing gas comprises exposing the gate dielectric material to a nitrogen-containing gas combined with O₂, CO, or CO₂.

13. The method according to claim 7, wherein converting the portion of the gate dielectric material comprises treating the gate dielectric material with a gate dielectric material reduction process, wherein the gate dielectric material reduction process comprises exposing the gate dielectric material to a hydrogen-containing gas at a temperature of about 450 to 750 degrees C., and wherein the exposure to the hydrogen-containing gas causes oxygen to be removed from the gate dielectric material and form the conductive material.

14. The method according to claim 7, wherein converting the portion of the gate dielectric material comprises a catalytic reaction process, wherein the catalytic reaction process comprises exposing the gate dielectric material to a catalyst or a metal organic precursor at a temperature sufficient to cause a catalytic reaction for about 30 minutes or less.

15. The method according to claim 7, wherein forming the gate dielectric material comprises forming a gate dielectric material comprising at least one metal element, and wherein converting the portion of the gate dielectric material comprises forming a conductive material comprising the at least one metal element.

16. A method of manufacturing a semiconductor device, the method comprising:
providing a workpiece;
depositing a gate dielectric material over the workpiece;
forming a conductive material over the gate dielectric material using an in-situ process;
depositing a layer of semiconductive material over the conductive material; and
patterning the layer of semiconductive material, the conductive material, and the gate dielectric material to form at least one transistor, wherein the gate dielectric material comprises a gate dielectric of the at least one transistor, and wherein the conductive material and the layer of semiconductive material comprises a gate electrode of the at least one transistor.

17. The method according to claim 16, wherein depositing the gate dielectric material comprises placing the workpiece in a chamber and forming the gate dielectric material over the workpiece, and wherein forming the conductive material comprises:
without removing the workpiece from the chamber, introducing a first substance into the chamber to form the conductive material.

18. The method according to claim 17, wherein forming the gate dielectric material over the workpiece comprises introducing at least one second substance and a third substance into the chamber, the at least one second substance comprising at least one metal element.

19. The method according to claim 18, wherein introducing the at least one second substance into the chamber comprises introducing at least one metal element comprising Hf, Zr, La, Al, Ti, Ta, Sr, Bi, Ba, Y, Pr, Pb, Sm, Eu, Nd, Sc, Mg, Co, W, Ir, Be, Ce, Gd, Dy, Ga, and/or Pd, or combinations thereof.

20. The method according to claim 18, wherein forming the conductive material comprises discontinuing introducing the third substance into the chamber, and continuing to introduce the at least one second substance into the chamber, wherein the first substance is different than the third substance.

21. The method according to claim 18, wherein forming the conductive material comprises continuing introducing the at least one second substance into the chamber, wherein introducing the first substance comprises introducing the third substance in a different amount than the amount used to form the gate dielectric material.

22. The method according to claim 16, wherein depositing the gate dielectric material comprises depositing Al₂O₃, AlₓSi_{y}O_{z}, BaTiO₃, SrTiO₃, (Ba,Sr)TiO₃, BeAl₂O₄, CeO₂, CeHfO₄, CoTiO₃/Si₃N₄, Dy₂O₃, DyScO₃, EuAlO₃, Ga₂O₃, Gd gallium oxide, GdScO₃, HfO₂, Hf silicate, HfₓTa_{y}O_{z}, HfTiO₄, La₂O₃, LaAlO₃, LaScO₃, La₂SiO₅, MgAl₂O₄, NdAlO₃, PrAlO₃, SmAlO₃, SrTiO₃, Ta₂O₅, Ta₂O₅—TiO₂, TiO₂, TiO₂/Si₃N₄, Y₂O₃, YₓSi_{y}O_{z}, ZrO₂, Zr—Al—O, Zr silicate, ZrTiO₄, SnTiO₄, Pb(Zr,Ti)O₃, materials containing these elements at different stoichiometric compositions, or combinations or multiple layers thereof.

23. The method according to claim 16, wherein forming the conductive material comprises forming a conductive material comprising Hf, Zr, La, Al, Ti, Ta, Sr, Bi, Ba, Y, Pr, Pb, Sm, Eu, Nd, Sc, Mg, Co, W, Ir, Be, Ce, Gd, Dy, Ga, and/or Pd, or combinations thereof.

24. A semiconductor device, comprising:
a workpiece;
a gate dielectric disposed over the workpiece, the gate dielectric comprising at least one metal element;
a conductive material disposed over the gate dielectric, the conductive material comprising the at least one metal element of the gate dielectric; and
a semiconductive material disposed over the conductive material, wherein the conductive material and the semiconductive material comprise a gate electrode of at least one transistor.

25. The semiconductor device according to claim 24, wherein the gate dielectric comprises a dielectric constant of about 4.0 or greater.

26. The semiconductor device according to claim 24, wherein the gate dielectric comprises Hf, Zr, La, Al, Ti, Ta, Sr, Bi, Ba, Y, Pr, Pb, Sm, Eu, Nd, Sc, Mg, Co, W, Ir, Si, Be, Ce, Gd, Dy, Ga, and/or Pd combined with O, N, C, and/or Si.

27. The semiconductor device according to claim 24, wherein the at least one metal element comprises Hf, Zr, La, Al, Ti, Ta, Sr, Bi, Ba, Y, Pr, Pb, Sm, Eu, Nd, Sc, Mg, Co, W, Ir, Be, Ce, Gd, Dy, Ga, and/or Pd, or combinations thereof.

28. The semiconductor device according to claim 24, wherein the transistor comprises a PMOS or NMOS transistor, or a CMOS device comprising both a PMOS transistor and an NMOS transistor.

29. The semiconductor device according to claim 24, wherein the gate dielectric comprises an effective electrical thickness of about 20 Angstroms or less.
